(19) United States
(12) Patent Application Publication
(10) Pub. No.: US 2026/0221542 A1
(43) Pub. Date: Jul. 30, 2026

(54) CONTACTING CIRCUIT BOARD

(71) Applicant: HOPPECKE SYSTEMTECHNIK GMBH, Zwickau (DE)

(72) Inventors: Simon RICHTER, Schönheide (DE); Stefan REINHOLD, Zwickau (DE); Magnus TRAPP, Bad Wünnenberg (DE)

(21) Appl. No.: 19/144,652

(22) PCT Filed: Mar. 1, 2024
(86) PCT No.: PCT/EP2024/055441

§ 371 Date: Jun. 30, 2025

(30) Foreign Application Priority Data
Mar. 21, 2023 (EP) 23163255.5

(51) Int. Cl. H01M 10/6571; H01M 10/0525; H01M 10/42; H01M 10/48; H01M 10/615; H01M 10/63; H05K 1/02

(52) U.S. Cl. CPC H01M 10/6571; H01M 10/0525; H01M 10/425; H01M 10/482; H01M 10/615; H01M 10/63; H05K 1/0212; H05K 1/0277; H05K 2201/10037

(57) ABSTRACT

The disclosure relates to a contacting circuit board for an energy storage module, in particular a lithium-ion battery, having a flexible plastic substrate which provides first conductor tracks for an electric connection of a sensor circuit board to connection poles of the energy storage module, wherein the plastic substrate has a first large side and a second large side oriented parallel hereto, wherein one of the two large sides is equipped with a heating device and wherein contacting elements interacting with the connection poles of the energy storage module are provided which are spaced apart from the plastic substrate.

### CROSS-REFERENCE TO RELATED APPLICATIONS

This application is a U.S. National Phase Application under 35 U.S.C. 371 of International Application No. PCT/EP2024/055441, filed on Mar. 1, 2024, which claims priority to European Patent Application No. 23163255.5, filed on Mar. 21, 2023, the entire contents of which is incorporated by reference herein.

### FIELD

The disclosure relates to a contacting circuit board for an energy storage module, in particular a lithium-ion battery, having a flexible plastic substrate which provides first conductor tracks for an electric connection of a sensor circuit board to connection poles of the energy storage module. The disclosure also relates to an energy storage module, in particular a lithium-ion battery, which comprises a plurality of electrically interconnected lithium-ion cells, wherein the energy storage module is equipped with a contacting circuit board.

### BACKGROUND

This section provides background information related to the present disclosure which is not necessarily prior art.

From prior art according to DE 10 2015 010 925 A1, a cell connector unit and/or a cell voltage tapping unit is known. This unit has a base body which can also be referred to as a circuit board and which can be made of plastic. This base body is equipped with a temperature control unit that can be electrical, namely in the design of a heating device. In this case, a resistance wire extending in a meandering pattern can be provided as a heating device.

Furthermore, from prior art according to US 2020/036064 A1, a battery module with several battery cells is known, wherein the cell terminals of the battery cells are mutually connected via conductor rails. These conductor rails are covered by heating groups, each of which comprises a thermally conductive pad. Each pad is in contact with a heat conducting distribution plate, wherein heating elements are attached to the heat conducting distribution plates.

A contacting circuit board as described above, i.e. a contacting circuit board of this generic type, is known from EP 3 715 171 B1.

The contacting circuit board known from EP 3 715 171 B1 has a flexible plastic substrate. This is designed in the form of a film, for example.

The plastic substrate has first conductor tracks which in the final assembled state serve to connect the sensor circuit board to connection poles of the energy storage module. For this purpose, the contacting circuit board has contacting elements which are electrically connected to the connection poles of the energy storage module in the final assembled state.

The first conductor tracks having the plastic substrate are electrically connected at one end to the contacting elements interacting with the connection poles of the energy storage module and are electrically connected to a sensor circuit board at the other end, so as to form an electrically conducting connection between the sensor circuit board and the connection poles of the energy storage module. In this case, the sensor circuit board can be designed as a separate board or as a component of the contacting circuit board.

The sensor circuit board comprises an electronic circuit which is adapted to evaluate voltage measurements.

The energy storage module comprises a plurality of electrically interconnected cells. In this case, each cell has two connection poles, namely a negative connection pole on the one side and a positive connection pole on the other. For voltage measurement, the individual cells of the energy storage module are electrically connected to the sensor circuit board, for which purpose the contacting circuit board serves in the manner already described above.

Voltage values detected by the sensor circuit board can be evaluated by means of the electronic circuit provided by the sensor circuit board. However, it is also possible to compare voltage values of individual cells of the energy storage module to each other. In this manner, in particular, also the charge level can be determined, and not only that of the energy storage module as such, but also that of the individual cells.

In the final assembled state, the contacting circuit board is placed on top of the energy storage module from above in the vertical direction, with the position of the contacting circuit board being fixed by connecting, e.g. soldering or welding, the contacting elements of the contacting circuit board to the associated connection poles of the energy storage module. Furthermore, the contacting circuit board can be additionally glued or otherwise connected to the top of the energy storage module or to the top of the cells of the energy storage module.

Although the contacting circuit board already known from EP 3 715 171 B1 has proven itself in everyday practical use, there is a need for improvement, particularly with regard to an extended range of applications. It is therefore the object of the disclosure to further develop the design of a contacting circuit board of the type mentioned above in such a way that an extended range of applications is obtained.

### SUMMARY

This section provides a general summary of the disclosure, and is not a comprehensive disclosure of its full scope or all of its features.

To achieve this object, the disclosure proposes a contacting circuit board of the generic kind which is characterized in that the plastic substrate has a first large side and a second large side oriented parallel hereto, wherein one of the two large sides is equipped with a heating device and wherein contacting elements interacting with the connection poles of the energy storage module are provided which are spaced apart from the plastic substrate.

The plastic substrate which is designed for example as a flexible plastic film has two large sides which are aligned parallel to each other. One of these two large sides faces the energy storage module in the final assembled state. However, the other side of the plastic substrate opposite this side faces away from the storage module in the final assembled state.

According to the disclosure, it is provided that the plastic substrate includes a heating device, namely one of the two large sides is equipped with a heating device. In this case, it is preferred that the side of the plastic substrate which faces the energy storage module in the final assembled state includes the heating device.

As a result, the contacting circuit board according to the disclosure provides two functionalities. On the one side, first conductor tracks are provided in the conventional way, which conductor tracks serve the electrical connection of a sensor circuit board to connection poles of the energy storage module in accordance with prior art. On the other side, the contacting circuit board is equipped with a heating device which allows heat to be applied to the energy storage module or to the cells of the energy storage module, if required. In order to enable the most direct possible heat transfer from the heating device to the energy storage module or to the cells provided by the energy storage module, the heating device is preferably arranged on the side of the plastic substrate that faces the energy storage module in the final assembled state. However, according to an alternative, the heating device can be also arranged on the side of the plastic substrate which faces away from the energy storage module in the final assembled state. In this case, the plastic substrate of the contacting circuit board has a disadvantageous thermal insulating effect, but due to the very thin design of the plastic substrate, for example as a flexible plastic film, there is only a slight deterioration in heat transfer in the case of use as intended. On the other hand, the arrangement of the heating device on the large side of the plastic substrate which faces away from the energy storage module in the final assemble state has the advantage that the intended and correct alignment of the heating device in relation to the individual cells provided by the energy storage module can be directly inspected by sight, i.e. without additional aids, during assembly and/or maintenance.

Due to the technology, charging at low temperatures is not possible in all energy storage modules, in particular lithium-ion batteries. The contacting circuit board according to the disclosure provides remedy here because a predetermined temperature for the individual cells of the energy storage module can be achieved by operating the heating device provided by the contacting circuit board as required and as desired, which enables optimum charging of the cells. The use of separate heating foils known from prior art can thus be advantageously dispensed with. The contacting circuit board which is anyway provided serves as a replacement for the heating foil in its design according to the disclosure, as it also provides the additional functionality of the heating device. Accordingly, the contacting circuit board according to the disclosure has an extended range of applications, as it not only serves to electrically connect a sensor circuit board to the connection poles of the energy storage module, but also offers the possibility of heating the energy storage module or the cells provided by it, if necessary.

Advantageously, the integration of a heating device into a contacting circuit board according to the disclosure is particularly cost-effective because no additional heating device, for example in the design of a heating foil, is required and other components are not needed either. The finished design of an energy storage module using a contacting circuit board according to the disclosure therefore proves to be simpler and therefore more cost-effective in terms of both manufacture and assembly compared to prior art.

The arrangement of the heating device on the contacting circuit board in accordance with the disclosure also has the advantage that the heating device can be electrically connected to the energy storage module in a simple way so that in the case of use as intended the heating device is supplied from the total voltage of the energy storage module. Alternatively, an external power supply can of course also be provided for the heating device. However, the electrical connection of the heating device to the energy storage module is advantageous, as no additional components and/or assembly steps are required during production.

All in all, the contacting circuit board according to the disclosure provides a circuit board which is multi-functional in that in the case of intended use it ensures a proper electrical connection between a sensor circuit board and the connection poles of the energy storage module, on the one side, but also provides a heating device which, if necessary, heats up the energy storage module, on the other side.

According to the disclosure, contacting elements interacting with the connection poles of the energy storage module are provided which are spaced apart from the plastic substrate. Accordingly, the contacting elements are not provided by the flexible plastic substrate of the contacting circuit board. Compared to prior art, this results in a structure of the contacting circuit board which is much less filigree, which is a particular advantage concerning an assembly of the contacting circuit board, especially because an automated arrangement of the contacting circuit board on an energy storage module can be achieved much more easily.

The contacting elements—also referred to as cell tapping—are preferably formed together with the associated conductor tracks in one production step, although a design of the contacting elements separate from the conductor tracks is also conceivable. The sole important factor is that the contacting elements are not supported by the contacting circuit board. The contacting elements are rather designed so as to be spaced apart from the plastic substrate, hence arranged beside the plastic substrate in the final assembled state. Connecting sections which are still to be described in more detail are used for electrical contacting of the contacting elements with the associated conductor tracks.

In prior art according to EP 3 715 171 B1 already mentioned above, the flexible plastic substrate of the contacting circuit board provides a main branch on the one side and strip-like secondary branches on the other side. The end regions of the strip-like secondary branches opposite the main branch each provide contact areas that carry the contacting elements that interact with the connection poles of the energy storage. In contrast to this design, the strip-like secondary branches are not used in the design according to the disclosure. Instead, the contacting elements are spaced apart from the plastic substrate, i.e. are formed outside of it, and are electrically connected directly to the first conductor track of the contacting circuit board via a corresponding electrical connection. The ladder-shaped design of the plastic substrate, which is preferred due to the heating device provided in accordance with the disclosure, can therefore advantageously remain unchanged.

According to a further feature of the disclosure, it is provided that a first conductor track leads into a first connection path to which a contacting element is electrically connected. The connection path thus serves as an electrical bridge between a first conductor track and a contacting element. In this case, also more than only one contacting element can preferably be connected to the connection path. The connection path therefore offers the advantage of being able to electrically connect one or more contacting elements to a first conductor track in a simple manner. In this case, the use of two parallel-connected contacting elements offers the particular advantage of increasing the reliability of cell voltage measurement. In addition, the design of a connection path means that a welded connection is not required, which simplifies production. It is then only necessary to electrically connect the contacting elements to the cell poles during assembly, which is preferably done by welding.

According to a further feature of the disclosure, a preferably s-shaped connecting section is provided for an electrical connection of a contacting element to a connection path. Accordingly, a contacting element is electrically connected to a connection path under interposition of a connecting section. Such a connecting section offers the advantage of being able to position the contacting element interacting with it in relation to the plastic substrate. This assists a positionally accurate alignment of the contacting elements for the purpose of electrical connection to an associated connection pole of the energy storage module. To increase positional variability, the connecting section is preferably s-shaped. This allows both elongation and bending in relation to the plastic substrate. Any inaccuracies of fit between the position of the contacting circuit board on the electrical storage module on the one hand and the position of the connection poles of the energy storage module on the other can thus be compensated for in an advantageous manner. This also makes it possible to compensate for any manufacturing tolerances.

According to a further feature of the disclosure, it is provided that the connecting portion and the associated contacting element are formed as one piece preferably from nickel and are soldered to the connection path. According to this embodiment, the contacting element is formed by a so-called nickel pad that can be directly soldered to the associated connection path of the contacting circuit board via the connecting section integrally provided by said nickel pad. This also supports simple and cost-effective production.

According to a further feature of the disclosure, it is provided that the heating device includes a second connector track made of copper which is applied to the plastic substrate, preferably by printing.

The heating device is virtually designed as a heating helix formed from a conductor track applied to the plastic substrate. The conductor track preferably consists of copper and is printed onto the plastic substrate, for example. The result is a contacting circuit board which has a plastic substrate as a carrier material that is equipped with first conductor tracks on a first side and with second conductor tracks on a second side. In this case, the first conductor tracks serve the electrical connection of a sensor circuit board to connection poles of the energy storage module in the manner already described, whereas the second conductor tracks designed as a heating helix form the heating device according to the disclosure. The design of the heating device proves to be particularly simple and cost-effective. In particular, this embodiment allows a contacting circuit board to be formed in a single work step, which contacting circuit board also provides the functionality of the heating device.

According to a further feature of the disclosure, it is provided that the second conductor track is formed in a meandering pattern, at least in sections. This creates compact heating resistors which, thanks to their arrangement on the plastic substrate of the contacting circuit board, are positioned directly above an associated cell of the energy storage module in the final assembled state. This results in an overall compact heating device that also enables precise positioning in relation to the individual cells of the energy storage module.

In this context, according to a further feature of the disclosure, it is proposed that the plastic substrate has a geometrical design which corresponds to the cell arrangement within the energy storage module. For example, the plastic substrate can be designed in the form of a ladder, wherein the plastic substrate has strip sections which, in the final assembled state, lie directly above a cell of the energy storage module. These strip sections have the meandering second conductor tracks of the heating device according to the disclosure on their underside facing the respective cell. This ensures a direct allocation between the second conductor tracks of the heating device and the respective cell of the energy storage module in a precise position.

According to a further feature of the disclosure, it is provided that the second conductor track is designed for electrical connection to the energy storage module. This makes it possible in an advantageous way to be able to supply the heating device from the total voltage of the energy storage module. From the structural point of view, this can be accomplished, for example, by the second conductor tracks leading into contacts which in turn are electrically connected to connection poles of the energy storage module when used as intended.

According to a further feature of the disclosure, it is provided that the contacting circuit board has temperature sensors. These are coupled to the sensor circuit board by means of corresponding conductor tracks so that an evaluation of the cell temperature measurements provided by the temperature sensors can be carried out by means of the electronic circuit of the sensor circuit board when used as intended. In this case, the evaluation of the detected cell temperatures can be used not only to monitor cell temperature, but also to control the heating device. In particular, the temperature values can be used to determine at the beginning of the charging process whether or not the heating device should be switched on for an optimized charging process. Of course, in addition, automatic switch-off of the heating device is enabled when the cell temperature necessary for an optimized charging process is reached.

According to a further feature of the disclosure, it is provided that the plastic substrate is equipped on one of its two large sides with a third conductor track which provides a balancing resistor. According to this embodiment, the contacting circuit board has a third conductor track. This provides at least one balancing resistor. Preferably, several such balancing resistors are provided, namely one resistor per parallel group. In this case, the conductor track is formed on one of the two large sides of the plastic substrate. In this context, it is preferred that the large side of the plastic substrate is equipped with the third conductor track which faces away from the energy storage module in the final assembled state. Accordingly, the heating device is provided by a first large side of the plastic substrate, whereas the third conductor track is formed on the other one of the two large sides of the plastic substrate. Alternatively, both the third conductor track and the heating device can be provided by one and the same large side of the plastic substrate. However, in particular for space reasons, it is preferred to equally use both large sides of the plastic substrate to accommodate the individual conductor tracks, which is why it is also desirable for reasons of simplified production to use one of the two large side of the plastic substrate for accommodating the heating device and the other of the two large sides for accommodating the first and also the third conductor track.

During charging of the energy storage module, passive balancing serves to charge all cells of the energy storage module equally. In this case, passive balancing only works in the end-of-charge range, i.e. when the cells of the energy storage module are almost fully charged. Through the balancing, a balancing resistor is connected in parallel to each cell that has already reached the charging end voltage, which causes the voltage to be limited to the charging end voltage. In the further course, this cell is continued to be charged only slightly or even discharged slightly, while the other cells, which have not yet reached the charging end voltage, are continued to receive full supply of charging current. The power of the parallel resistor is adapted to the charging current, as the excess energy occurs in the form of heat at the resistor. The advantage of this balancing method is, in particular, that it is cost-effective and technically easy to implement.

According to prior art, the balancing resistors for passive balancing are accommodated on a circuit board of a battery management system provided for this purpose. A drawback of this pre-known arrangement is that the thermal management only allows small balancing currents. Furthermore, different voltage situations of the cell chemistries NMC (lithium nickel manganese cobalt), LFP (lithium iron phosphate) and LTO (lithium titanium oxide) are a considerable drawback in the resistor design in a modular battery management system.

The accommodation of the balancing resistors not on a battery management system circuit board, but on a flexible contacting circuit board, as envisaged in the disclosure, overcomes these disadvantages. The high heat capacity of the cells of the energy storage module ensures good heat dissipation, which makes significantly larger balancing currents possible. Furthermore, the arrangement of the balancing resistors on the flexible contacting circuit board makes it possible to adapt the resistance to the voltage levels of the cells. This results in a significant increase in the performance of the passive balancing.

In this context, the disclosure proposes an independently protectable contacting circuit board for an energy storage module, in particular a lithium-ion battery, having a flexible plastic substrate that provides first conductor tracks for electrical connection of a sensor circuit board to connection poles of the energy storage module, the plastic substrate having a first large side and a second large side oriented parallel hereto, one of the two large sides being equipped with a heating device, and the plastic substrate being equipped, on its side facing away from the energy storage module in the final assembled state, with a third conductor track which provides a balancing resistor.

The disclosure proposes an independently protectable contacting circuit board which has a heating device on the one hand and a balancing resistor on the other hand. The heating device is preferably arranged on one side of the plastic substrate of the contacting circuit board, whereas the balancing resistor is located on the other side of the plastic substrate. With regard to the heating device and the balancing resistor used in combination with it, the advantages already explained for the heating device on the one hand and for the balancing resistor on the other hand arise jointly.

According to a further feature of the disclosure, it is provided that the third conductor track is electrically connected to the first conductor tracks. In this manner, a direct electric coupling of the first conductor tracks to the third conductor track providing a balancing resistor is given. The result is a simple structure of the contacting circuit board which also allows all conductor tracks to be applied to the flexible plastic substrate of the contacting circuit board in a simple manner by printing.

As already stated above, according to a further feature of the disclosure, it is preferably the side of the plastic substrate facing away from the energy storage module in the final assembled state, that is equipped with the third conductor track and/or the first conductor tracks. Accordingly, the heating device or the second conductor track provided by the heating device is arranged on the side of the plastic substrate that faces the energy storage module in the final assembled state.

The disclosure also proposes an energy storage module, in particular a lithium-ion battery, which has a plurality of electrically interconnected lithium-ion cells, characterized by a contacting circuit board of the type described above, i.e. of the type according to the disclosure. An energy storage module of this kind has the advantages already explained above with reference to the contacting circuit board in accordance with the disclosure.

According to a further feature of the disclosure, it is provided that the contacting circuit board is electrically connected to pole connections provided by the energy storage module, in which case the large side of the plastic substrate which faces the energy storage module has the heating device. An energy storage module equipped in this way also has the advantages already explained above with reference to the contacting circuit board.

Further areas of applicability will become apparent from the description provided herein. The description and specific examples in this summary are intended for purposes of illustration only and are not intended to limit the scope of the present disclosure.

### DRAWINGS

The drawings described herein are for illustrative purposes only of selected embodiments and not all possible implementations, and are not intended to limit the scope of the present disclosure.

Further features and advantages of the disclosure will become apparent from the following description with reference to the attached drawing figures in which

FIG. 1 shows a schematic top view of the side of a contacting circuit board facing an energy storage module in the final assembled state;

FIG. 2 shows a schematic view of a part of a heating device provided by the side of the contacting circuit board facing the energy storage module; and

FIG. 3 shows a schematic detailed view of the side of the contacting circuit board facing away from the energy storage module in the final assembled state and having the first and the third conductor tracks.

Corresponding reference numerals indicate corresponding parts throughout the several views of the drawings.

### DETAILED DESCRIPTION

Example embodiments will now be described more fully with reference to the accompanying drawings.

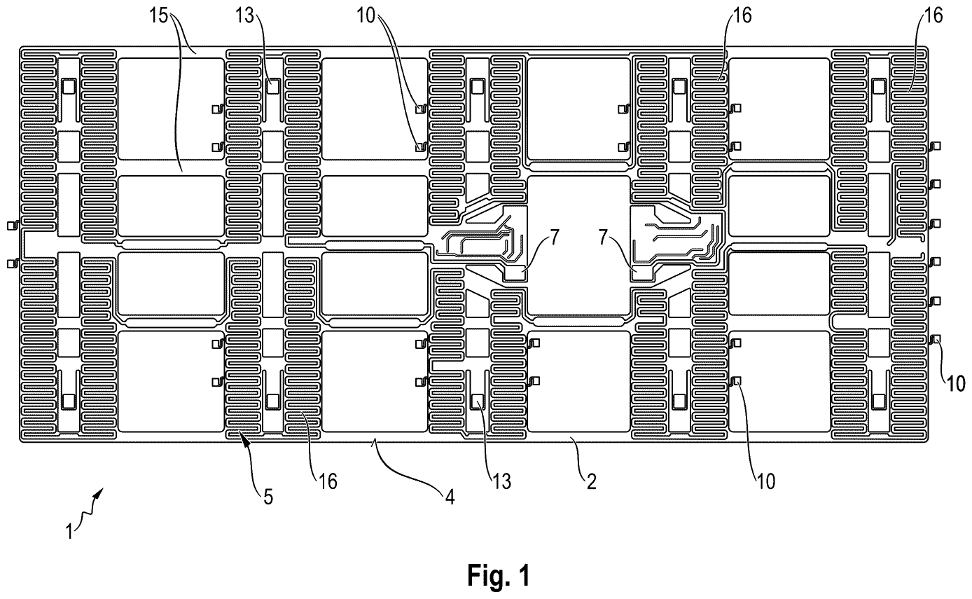

A contacting circuit board 1 according to the disclosure is schematically shown in FIG. 1.

The contacting circuit board 1 comprises a flexible plastic substrate 2 which, for example, is designed as a flexible plastic film. In the illustrated embodiment, the plastic substrate 2 is ladder-shaped and has longitudinal sections 15 on the one side and transverse sections 16 on the other side.

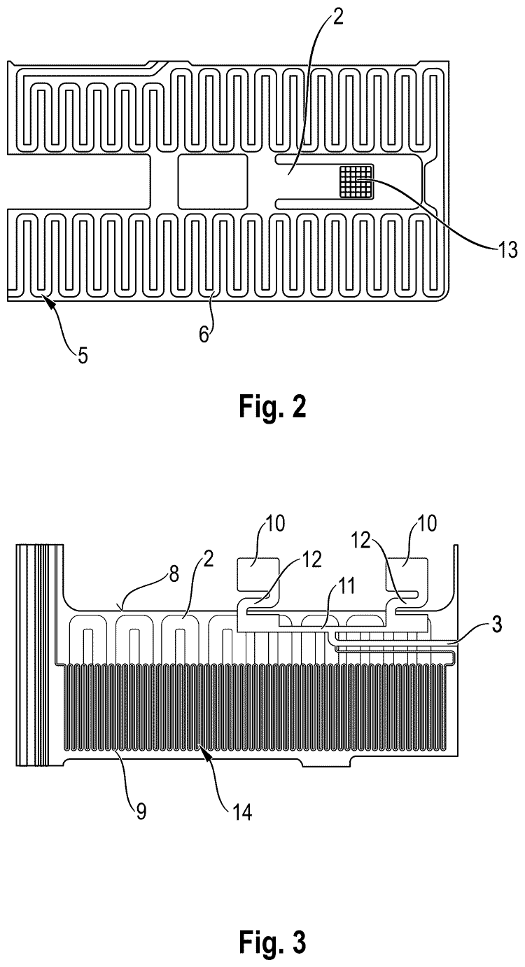

FIG. 1 shows the side 4 of the contacting circuit board facing an energy storage module in the final assembled state, which side can also be referred to as the large side 17. The side 4 of the plastic circuit board 1 facing the energy storage module in the final assembled state is equipped with a heating device 5 according to the disclosure. The heating device 5 has a conductor track 6 applied to the plastic substrate, preferably by printing. This context is particularly evident from the detailed view in FIG. 2.

The conductor track 6 of the heating device 5 is designed in a meander shape, at least in sections, as can also be seen from the illustration in FIG. 2.

The meandering course of the conductor tracks 6 virtually provides heating resistors which, when energized, heat the interacting cells of the energy storage module.

As can be seen from the illustration in FIG. 1, the conductor track 6 is designed to run in a meandering shape in the region of the transverse sections 16 of the plastic substrate 2. These transverse sections 16 are located directly above the respective cells of the energy storage module in the final assembled state of the contacting circuit board 1. This ensures direct heat transfer from the heating device 15 to the associated cells of the energy storage module.

As can be seen from a combined view of FIGS. 1 and 2, the contacting circuit board 1 also has temperature sensors 13. In the final assembled state of the contacting circuit board, these interact with the associated cells of the energy storage module and enable cell temperature detection. The heating device 5 is switched on and off by means of an electronic circuit, preferably depending on the cell temperatures detected by the temperature sensors 13.

The heating device 5 is preferably supplied from the total voltage of the energy storage module, for which purpose the conductor track 6 of the heating device 5 leads into corresponding contacts. In the intended use, this contact is used to realize an electrical connection between the heating device 5 and the energy storage module.

The flexible plastic substrate 2 also provides first conductor tracks 3 for electrical connection between a sensor circuit board and the connection poles of the energy storage module. The first conductor tracks 3 are formed on the side facing away from the energy storage module in the final assembled state, i.e. the large side 18 of the plastic substrate 2, as can be seen from the detailed representation according to FIG. 3. For electrical contacting of the first conductor tracks 3 with one or more sensor circuit boards not specifically shown in the Figures, corresponding contacts 7 are provided, as can be seen in particular from the illustration in FIG. 1.

On the connection pole side, the contacting circuit board provides contacting elements 10. These are electrically connected to a first conductor track 3. For this purpose, a connection path 11 is provided, which is provided by the plastic substrate 2 and which the first conductor track 3 leads into electrically. An s-shaped connecting section 12 is provided for electrical connection of a contacting element 10 to the connecting path 11. The contacting element 10 and the associated connecting section 12 are preferably designed in one piece. Nickel is the preferred material for the contacting element 10 and the connecting section 12. Soldering can preferably be used to connect a connecting section 12 to a connection path 11.

The advantage of the preferably s-shaped design of the connecting section 12 is that the position of the contacting element 10, which is not supported by the plastic substrate 2, can be changed in relation to the plastic substrate 2. This allows any manufacturing tolerances or positioning tolerances to be compensated for, so that proper contacting of a contacting element 10 with a connection pole of the energy storage module is ensured in any case. The s-shaped design of the connecting section 12 also serves to compensate for relative movements between the contact plate 1 and the energy storage module under dynamic load.

As can be seen from the illustration in FIG. 3, the plastic substrate 2 is equipped with a third conductor track 9, which provides a balancing resistor 14 on its side facing away from the energy storage module in the final assembled state. In this case, the third conductor track 9 is electrically connected to the first conductor track 3 and thus also to the contacting elements 10.

The contacting circuit board according to the disclosure provides a multifunctional contacting circuit board 1. This is because the contacting circuit board according to the disclosure not only accommodates first conductor tracks for electrically connecting a sensor circuit board to connection poles of the energy storage module. Furthermore, balancing resistors 14 and a heating device 5 are integrated into the contacting circuit board 1. The heating device 15 is located on one side of the plastic substrate 2, namely on the side 4 facing the energy storage module in the final assembled state. The other conductor tracks, i.e. the first conductor tracks 3 and the third conductor tracks 9, are arranged on the other side of the plastic substrate 2, namely on the side 8 facing away from the energy storage module in the final assembled state.

The foregoing description of the embodiments has been provided for purposes of illustration and description. It is not intended to be exhaustive or to limit the disclosure. Individual elements or features of a particular embodiment are generally not limited to that particular embodiment, but, where applicable, are inter-changeable and can be used in a selected embodiment, even if not specifically shown or described. The same may also be varied in many ways. Such variations are to be regarded as a departure from the disclosure, and all such modifications are intended to be included within the scope of the disclosure.

1. A contacting circuit board for an energy storage module, in particular a lithium-ion battery, having a flexible plastic substrate which provides first conductor tracks for an electric connection of a sensor circuit board to connection poles of the energy storage module, wherein the plastic substrate has a first large side and a second large side oriented parallel hereto, wherein one of the two large sides are equipped with a heating device and wherein contacting elements interacting with the connection poles of the energy storage module are provided which are spaced apart from the plastic substrate.

2. The contacting circuit board according to claim 1, wherein a first conductor track leads into a connection path to which a contacting element is electrically connected.

3. The contacting circuit board according to claim 1, wherein a preferably s-shaped connecting section under the interposition of which a contacting element is electrically connected to a connection path.

4. The contacting circuit board according to claim 3, wherein the connecting section and the contacting element are formed in one piece, preferably from nickel, and are soldered to the connection path.

5. The contacting circuit board according to of claim 1, wherein the heating device has a second conductor track from copper which is applied to the plastic substrate, preferably by printing.

6. The contacting circuit board according to claim 5, wherein the second conductor track is designed in a meandering shape, at least in sections.

7. The contacting circuit board according to claim 5, wherein the second conductor track is designed for electrical connection to the energy storage module.

8. The contacting circuit board according to claim 1, wherein the plastic substrate is equipped with a third conductor track providing a balancing resistor on its side facing away from the energy storage module in the final assembled state.

9. The contacting circuit board according to claim 8, wherein the third conductor track is electrically connected to the first conductor track.

10. The contacting circuit board according to claim 8, wherein the first of the two large sides is equipped with the heating device and the second of the two large sides is equipped with the third conductor track and preferably also with the first conductor tracks.

11. The contacting circuit board according to claim 1, wherein the large side aligned with the heating device is the side of the plastic substrate which faces the energy storage module in the final assembled state.

12. The contacting circuit board according to claim 1, wherein the large side equipped with the third conductor track and/or the first conductor tracks is the side of the plastic substrate which faces away from the energy storage module in the final assembled state.

13. An energy storage module, in particular lithium-ion battery, having a plurality of electrically interconnected lithium-ion cells including a contacting circuit board according to claim 1.

14. The energy storage module according to claim 13, wherein the contacting circuit board is electrically connected to pole connections provided by the energy storage module, wherein the large side of the plastic substrate facing the energy storage module has the heating device.
